(19) United States
(12) Patent Application Publication
(10) Pub. No.: US 2025/0029784 A1
(43) Pub. Date: Jan. 23, 2025

(54) MULTILAYER CERAMIC ELECTRONIC COMPONENT

(71) Applicant: Murata Manufacturing Co., Ltd., Nagaokakyo-shi (JP)

(72) Inventors: Shun IWATA, Nagaokakyo-shi (JP); Daichi TANIGUCHI, Nagaokakyo-shi (JP)

(21) Appl. No.: 18/907,928

(22) Filed: Oct. 7, 2024

Related U.S. Application Data
(63) Continuation of application No. PCT/JP2024/005057, filed on Feb. 14, 2024.

(30) Foreign Application Priority Data
Apr. 26, 2023 (JP) 2023-072301

(51) Int. Cl. H01G 4/12; H01G 4/012; H01G 4/30

(52) U.S. Cl. CPC H01G 4/12; H01G 4/012; H01G 4/30

(57) ABSTRACT

In a multilayer ceramic electronic component, the particle size of the ceramic on the first lateral surface of the inner layer portion is smaller than that in the central portion of the inner layer portion in the width direction. The particle size of the ceramic on the second lateral surface of the inner layer portion smaller than that in the central portion of the inner layer portion in the width direction. The particle size of the ceramic at the end of the second internal electrode layer on the first end surface of the inner layer portion is smaller than that in the central portion of the inner layer portion. The particle size of the ceramic at the end of the first internal electrode layer on the second end surface of the inner layer portion is smaller than that in the central portion of the inner layer portion.

### CROSS REFERENCE TO RELATED APPLICATIONS

This application claims the benefit of priority to Japanese Patent Application No. 2023-072301 filed on Apr. 26, 2023 and is a Continuation Application of PCT Application No. PCT/JP2024/005057 filed on Feb. 14, 2024. The entire contents of each application are hereby incorporated herein by reference.

### BACKGROUND OF THE INVENTION

### 1. Field of the Invention

The present invention relates to multilayer ceramic electronic components.

### 2. Description of the Related Art

Multilayer ceramic electronic components, such as multilayer ceramic capacitors, are manufactured by stacking a plurality of dielectric sheets. Depending on the type of multilayer ceramic electronic component, internal electrode layers are formed on the dielectric sheets to configure capacitors, resistors, inductors, varistors, filters, etc. In order to achieve downsizing and high-performance of the multilayer ceramic electronic components, the thinning and multi-layering of the dielectric sheets are underway. For instance, refer to Japanese Unexamined Patent Application, Publication No. 2001-267173.

However, Japanese Unexamined Patent Application, Publication No. 2001-267173 suggests that the internal electrode layers may not be thinned even if the thinning and multi-layering of the dielectric sheets are advanced. When the thinned dielectric sheets and the internal electrode layers are alternately stacked, and the edges of the internal electrode layers are alternately exposed at both end surfaces of the dielectric sheets in the length direction so as to alternately extend to the pair of external electrodes with differing polarities, a multilayer body is formed with a step generated due to the difference in thickness between the dielectric sheets and the internal electrode layers.

During the process of pressing the multilayer body where a step is generated due to the difference in thickness, the ceramic of the dielectric sheet may flow to fill the step generated due to the difference in thickness, leading to reduction in thickness of the dielectric sheets near the step, and further thinning the already thinned sheets.

However, when the dielectric sheets near the step become thinner, the grain boundaries in the thickness direction become very sparse, significantly reducing the electrical resistance. Consequently, when voltage is applied to the thinned dielectric sheet, excessive current flows, leading to electric field concentration, potentially causing insulation breakdown.

Furthermore, when current flows through the internal electrode layers, an edge effect occurs at the ends of the internal electrode layers near the step, where the electric field strength is higher than other regions of the internal electrode layers. This leads to increased electric field concentration at the ends of the internal electrode layers near the step, potentially causing insulation breakdown.

### SUMMARY OF THE INVENTION

Accordingly, example embodiments of the present invention provide multilayer ceramic electronic components, such as a multilayer ceramic capacitors, with high reliability. Specifically, the present invention provides multilayer ceramic electronic components each able to reduce or prevent an occurrence of an insulation breakdown at ends of internal electrode layers exposed to strong electric fields.

A multilayer ceramic electronic component according to an example embodiment of the present invention includes a multilayer body including stacked dielectric layers, and first and second internal electrode layers stacked on the dielectric layers, the multilayer body including first and second main surfaces on opposite sides in a lamination direction, first and second end surfaces on opposite sides in a length direction orthogonal or substantially orthogonal to the lamination direction, and first and second lateral surfaces on opposite sides in a width direction orthogonal or substantially orthogonal to both the lamination direction and the length direction, a first external electrode provided on the first end surface, and a second external electrode provided on the second end surface. The first internal electrode layers are electrically connected to the first external electrode. The second internal electrode layers are electrically connected to the second external electrode. The multilayer body includes an inner layer portion where the first and second internal electrode layers oppose each other. A particle size of ceramic included on a first lateral surface side of the inner layer portion is smaller than a particle size of the ceramic included in a central portion of the inner layer portion in the width direction. A particle size of the ceramic included on a second lateral surface side of the inner layer portion is smaller than a particle size of the ceramic included in the central portion of the inner layer portion in the width direction. A particle size of the ceramic included at an end of the second internal electrode layer on a first end surface side of the inner layer portion is smaller than a particle size of the ceramic included in the central portion of the inner layer portion. A particle size of the ceramic included at an end of the first internal electrode layer on a second end surface side of the inner layer portion is smaller than a particle size of the ceramic included in the central portion of the inner layer portion.

Example embodiments of the present invention multilayer ceramic electronic components, such as a multilayer ceramic capacitors, each with high reliability.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a multilayer ceramic electronic component according to a first example embodiment of the present invention.

FIG. 2 is a cross-sectional view along the line I-I in FIG. 1.

FIG. 3 is a cross-sectional view along the line II-II in

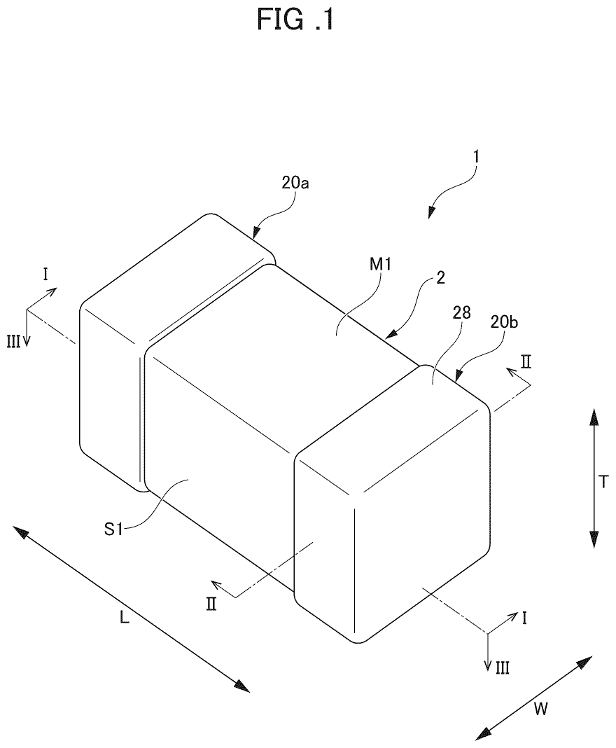

FIG. 1.

FIG. 4 is a cross-sectional view along the line III-III in FIG. 1.

FIG. 5 is a view in a second example embodiment of the present invention, corresponding to the cross-sectional view along the line II-II in FIG. 1.

FIG. 6 is a view illustrating an outline of a multilayer body core portion according to an example embodiment of the present invention.

FIG. 7 is a perspective view illustrating the polished inner layer portion according to an example embodiment of the present invention.

FIG. 8 is a perspective view illustrating the polished inner layer portion.

FIG. 9 is an LW cross-sectional view of the multilayer body, illustrating the distribution of ceramic particle size.

FIG. 10 is an LW cross-sectional view of the multilayer body, illustrating the distribution of ceramic particle size.

### DETAILED DESCRIPTION OF THE EXAMPLE EMBODIMENTS

### First Example Embodiment

An example embodiment of the present invention will be described based on a multilayer ceramic capacitor 1, which is an example of multilayer ceramic electronic components. FIG. 1 is a perspective view of the multilayer ceramic capacitor 1 according to the first example embodiment of the present invention.

### Multilayer Body

The multilayer body 2 includes a plurality of dielectric layers and a plurality of internal electrode layers, which are stacked. The multilayer body 2 preferably has a substantially rectangular or substantially rectangular parallelepiped shape. In the multilayer body 2, the direction of stacking the dielectric layers and the internal electrode layers is defined as the lamination direction T. The direction orthogonal or substantially orthogonal to the lamination direction T is defined as the width direction W. The direction orthogonal or substantially orthogonal to both the lamination direction T and the width direction W is defined as the length direction L.

In the multilayer body 2, two surfaces on opposite sides in the lamination direction T are defined as a first main surface M1 and a second main surface M2, respectively. In the multilayer body 2, two surfaces on opposite sides in the width direction W are defined as a first lateral surface S1 and a second lateral surface S2, respectively. Two surfaces on opposite sides in the length direction L are defined as a first end surface E1 and a second end surface E2, respectively. The mounting surface of the multilayer ceramic capacitor 1 is the second main surface M2. The mounting surface is the surface that opposes a wiring board when the multilayer ceramic capacitor 1 is mounted onto the wiring board.

As for the cross-sections of the multilayer body 2, the cross-section along the line I-I in FIG. 1 is defined as an LT cross-section. The cross-section along the line II-II in FIG. 1 is defined as a WT cross-section. The cross-section along the line III-III in FIG. 1 is defined as an LW cross-section.

The corners and the edge lines of the multilayer body 2 are preferably rounded. The corners refer to the portions where three surfaces of the multilayer body 2 intersect. The edge lines refer to the portions where two surfaces of the multilayer body 2 intersect. Irregularities such as recesses and protrusions may be provided partially or entirely on the main surfaces, the lateral surfaces, and the end surfaces.

### Dielectric Layers

The total number of the dielectric layers stacked in the multilayer body 2 is preferably between 15 and 2000 layers inclusive. The dielectric layers are primarily made from ceramic material. As examples of the ceramic material, dielectric ceramics including principal components such as BaTiO₃, CaTiO₃, SrTiO₃, CaZrO₃, etc., can be used. In addition to these principal components, the ceramic material may use dielectric ceramics containing additives such as, for example, Mn compounds, Fe compounds, Cr compounds, Co compounds, and Ni compounds, as secondary components.

The present example embodiment describes a multilayer ceramic electronic component, taking the multilayer ceramic capacitor 1 as an example of the multilayer ceramic electronic component.

When piezoelectric ceramics are used in the multilayer body 2, the multilayer ceramic electronic component defines and functions as a piezoelectric element. Specific examples of piezoelectric ceramic materials include PZT (lead zirconate titanate) based ceramic materials.

When semiconductor ceramics are used in the multilayer body 2, the multilayer ceramic electronic component functions as a thermistor element. Specific examples of semiconductor ceramic materials include spinel-based ceramic materials.

When magnetic ceramics are used in the multilayer body 2, the multilayer ceramic electronic component defines and functions as an inductor element. When the multilayer ceramic electronic component defines and functions as an inductor element, the internal electrode layers form coil-shaped conductors. Specific examples of magnetic ceramic materials include ferrite ceramic materials.

The thickness of each dielectric layer is, for example, preferably between about 0.5 μm and about 10 μm inclusive.

### Divisions of Multilayer Body

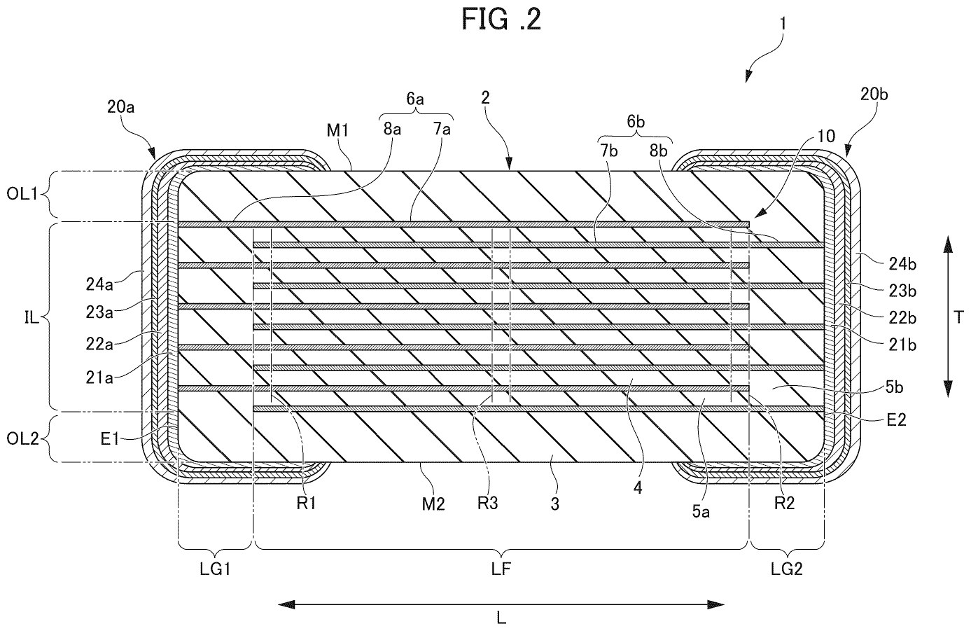

Based on FIG. 2, the divisions of the multilayer body 2 in the length direction L will be described. FIG. 2 is a cross-sectional view along the line I-I in FIG. 1. In the lamination direction T, the multilayer body 2 can be divided into a first main surface-side outer layer portion OL1, an inner layer range IL, and a second main surface-side outer layer portion OL2. The first main surface-side outer layer portion OL1, the inner layer range IL, and the second main surface-side outer layer portion OL2 are provided in this order from the first main surface M1 toward the second main surface M2 in the lamination direction T.

The first main surface-side outer layer portion OL1 is the portion between the first main surface M1 and a line drawn from the first end surface E1 to the second end surface E2 along the surface of the internal electrode layer closest to the first main surface M1. The second main surface-side outer layer portion OL2 is the portion between the second main surface M2 and a line drawn from the first end surface E1 to the second end surface E2 along the surface of the internal electrode layer closest to the second main surface M2. The inner layer range IL is the range sandwiched between the first main surface-side outer layer portion OL1 and the second main surface-side outer layer portion OL2. Namely, the inner layer range IL is the range between a line drawn from the first end surface E1 to the second end surface E2 along the surface of the internal electrode layer closest to the first main surface M1 and another line drawn from the second end surface E2 to the first end surface E1 along the surface of the internal electrode layer closest to the second main surface M2.

The first main surface-side outer layer portion OL1 is located on the first main surface M1 side of the multilayer body 2. The first main surface-side outer layer portion OL1 can include a plurality of dielectric layers between the first main surface M1 and a line drawn from the first end surface E1 to the second end surface E2 along the outermost surface of the internal electrode layer closest to the first main surface M1.

The second main surface-side outer layer portion OL2 is located on the second main surface M2 side of the multilayer body 2. The second main surface-side outer layer portion OL2 can include a plurality of dielectric layers between the second main surface M2 and a line drawn from the first end surface E1 to the second end surface E2 along the outermost surface of the internal electrode layer closest to the second main surface M2.

The first main surface-side outer layer portion OL1 is located on the first main surface M1 side, and includes a plurality of dielectric layers between the first main surface M1, the outermost surface of the inner layer range IL on the first main surface M1 side, and the extension line of the outermost surface.

The second main surface-side outer layer portion OL2 is located on the second main surface M2 side, and includes a plurality of dielectric layers between the second main surface M2, the outermost surface of the inner layer range IL on the second main surface M2 side, and the extension line of the outermost surface.

The inner layer range IL is the range sandwiched between the first main surface-side outer layer portion OL1 and the second main surface-side outer layer portion OL2.

Among the dielectric layers, the dielectric layers provided in the first main surface-side outer layer portion OL1 and the second main surface-side outer layer portion OL2 are referred to as the outer dielectric layers 3. Among the dielectric layers, the dielectric layers provided within the inner layer range IL are referred to as the inner dielectric layers 4.

The dimensions of the multilayer body 2 are not particularly limited. The dimension of the multilayer body 2 in the length direction L is referred to as the L dimension. The L dimension is, for example, preferably between about 0.2 mm and about 10 mm inclusive. The dimension of the multilayer body 2 in the width direction W is referred to as the W dimension. The W dimension is, for example, preferably between about 0.1 mm and about 5 mm inclusive. The dimension of the multilayer body 2 in the lamination direction T is referred to as the T dimension. The T dimension is, for example, preferably between about 0.1 mm and about 5 mm inclusive.

### L Gap

The divisions of the multilayer body 2 in the length direction L will be described. In the length direction L, the multilayer body 2 can be divided into a first end surface-side outer layer portion LG1, an L counter portion LF, and a second end surface-side outer layer portion LG2. The first end surface-side outer layer portion LG1, the L counter portion LF, and the second end surface-side outer layer portion LG2 are provided in this order from the first end surface E1 toward the second end surface E2 in the length direction L.

The first end surface-side outer layer portion LG1 is the portion where only the first internal electrode layers 6a oppose each other in the lamination direction T, and is the portion between the first main surface-side outer layer portion OL1 and the second main surface-side outer layer portion OL2. The second end surface-side outer layer portion LG2 is the portion where only the second internal electrode layers 6b oppose each other in the lamination direction T, and is the portion between the first main surface-side outer layer portion OL1 and the second main surface-side outer layer portion OL2. The L counter portion LF is the region sandwiched between the first end surface-side outer layer portion LG1 and the second end surface-side outer layer portion LG2. Thus, the L counter portion LF is the portion where the first internal electrode layers 6a and the second internal electrode layers 6b oppose each other in the lamination direction T. The L counter portion LF corresponds to the counter electrode portion of the internal electrode layers. The first end surface-side outer layer portion LG1 and the second end surface-side outer layer portion LG2 correspond to the extension electrode portion of the internal electrode layers. The counter electrode portion and the extension electrode portion will be described later. The first end surface-side outer layer portion LG1 and the second end surface-side outer layer portion LG2 are also referred to as the L gaps.

The first end surface-side outer layer portion LG1 is located on the first end surface E1 side, and located between the outermost surface on the first end surface E1 side and the outermost surface of the end of the second internal electrode layer 6b that is not connected to the first external electrode 20a.

The second end surface-side outer layer portion LG2 is located on the second end surface E2 side, and located between the outermost surface on the second end surface E2 side and the outermost surface of the end of the first internal electrode layer 6a that is not connected to the second external electrode 20b.

### W Gap

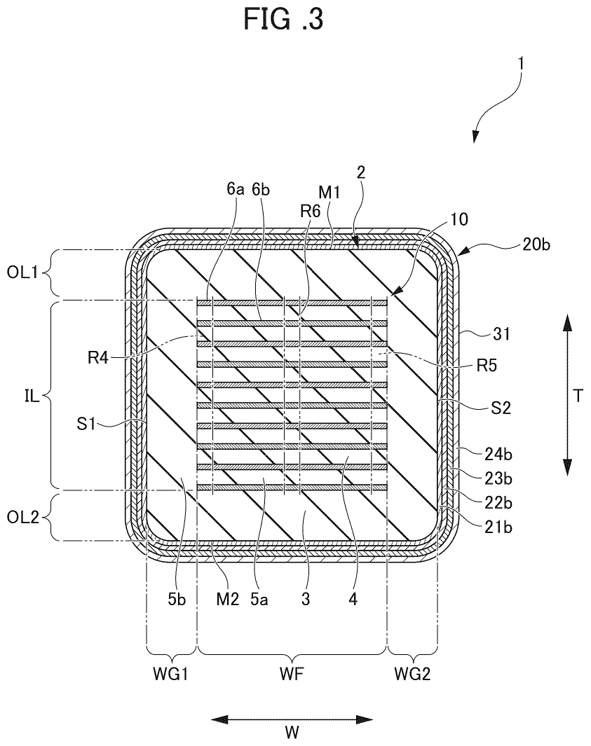

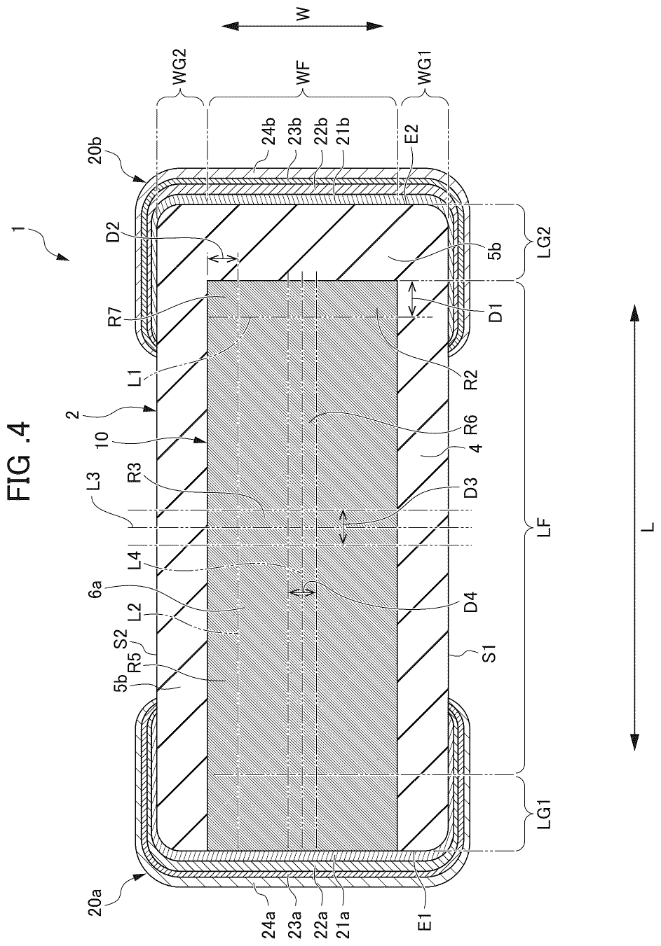

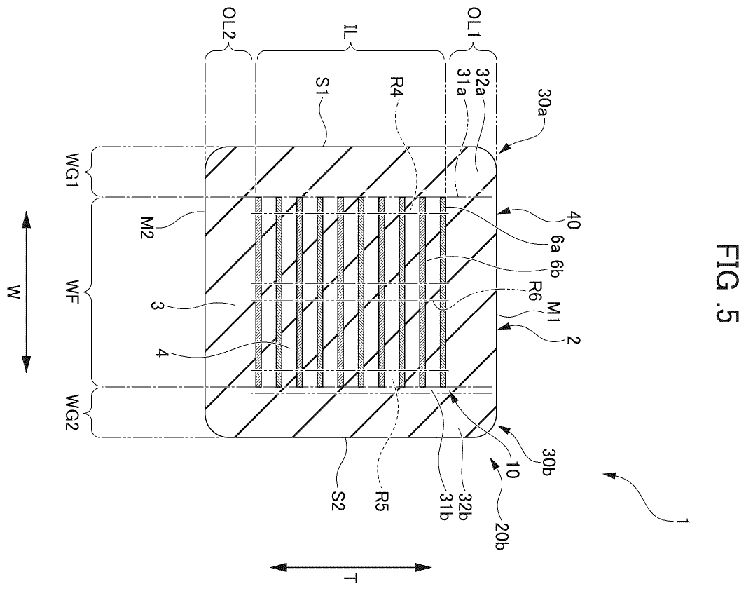

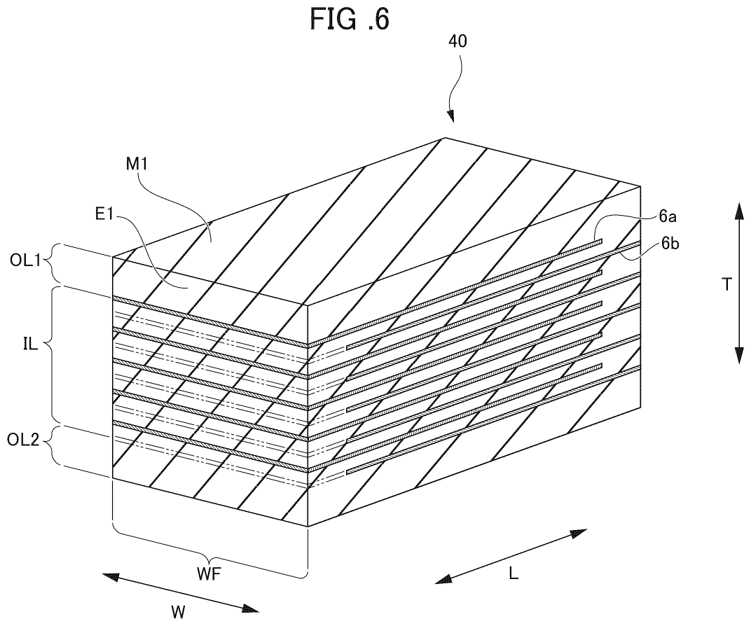

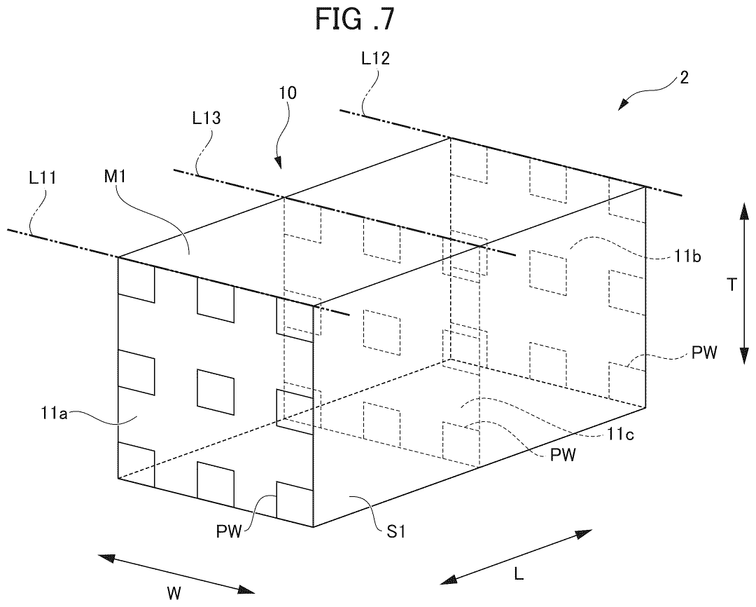

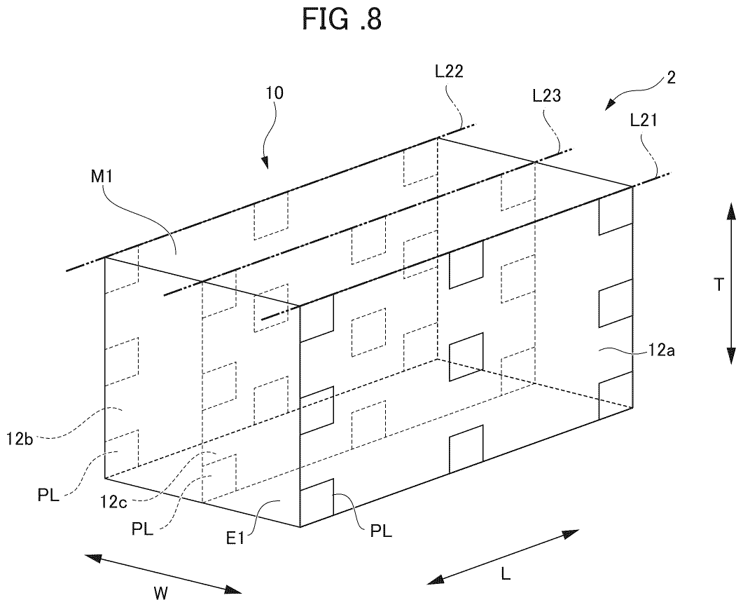

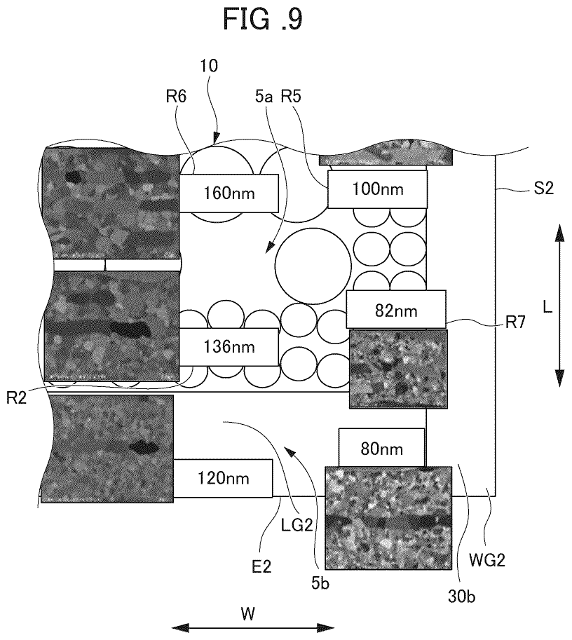

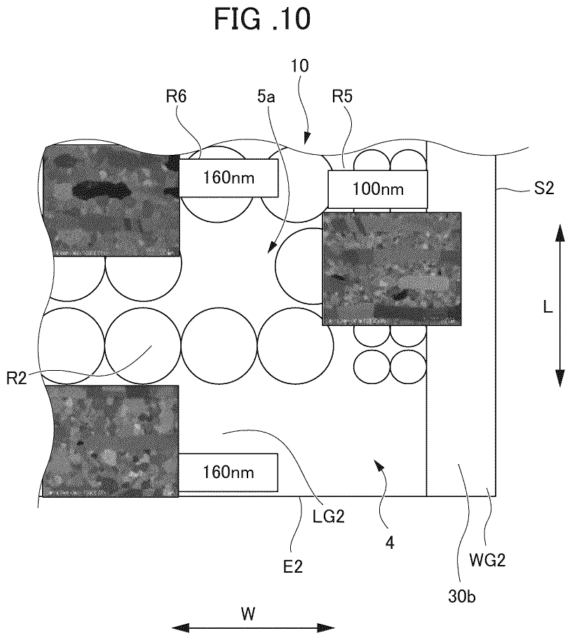

Based on FIG. 3, the divisions of the multilayer body 2 in the width direction W will be described. FIG. 3 is a cross-sectional view along the line II-II in FIG. 1. In the lamination direction T, the multilayer body 2 can be divided into the first main surface-side outer layer portion OL1, the inner layer range IL, and the second main surface-side outer layer portion OL2. The first main surface-side outer layer portion OL1 is the portion between the first main surface M1 and a line drawn from the first lateral surface S1 to the second lateral surface S2 along the outermost surface of the internal electrode layer closest to the first main surface M1. The second main surface-side outer layer portion OL2 is the portion between the second main surface M2 and a line drawn from the first lateral surface S1 to the second lateral surface S2 along the outermost surface of the internal electrode layer closest to the second main surface M2. The inner layer range IL is the range sandwiched between the first main surface-side outer layer portion OL1 and the second main surface-side outer layer portion OL2. Namely, the inner layer range IL is the area between a line drawn from the first lateral surface S1 to the second lateral surface S2 along the outermost surface of the innermost internal electrode layer closest to the first main surface M1 and another line drawn from the second lateral surface S2 to the first lateral surface S1 along the outermost surface of the innermost internal electrode layer closest to the second main surface M2. Among the dielectric layers, the dielectric layers provided in the first main surface-side outer layer portion OL1 and the second main surface-side outer layer portion OL2 are referred to as the outer dielectric layers 3. Among the dielectric layers, the dielectric layers provided within the inner layer range IL2 are referred to as the inner dielectric layers 4.

In the width direction W, the multilayer body 2 can be divided into the first lateral surface-side outer layer portion WG1, the W counter portion WF, and the second lateral surface-side outer layer portion WG2. The first lateral surface-side outer layer portion WG1, the W counter portion WF, and the second lateral surface-side outer layer portion WG2 are provided in this order from the first lateral surface S1 toward the second lateral surface S2 in the width direction W.

The W counter portion WF is the portion where the internal electrode layers oppose each other in the lamination direction T. The first lateral surface-side outer layer portion WG1 is the portion between the W counter portion WF, the first lateral surface S1, the first main surface-side outer layer portion OL1, and the second main surface-side outer layer portion OL2. The second lateral surface-side outer layer portion WG2 is the portion between the W counter portion WF, the second lateral surface S2, the first main surface-side outer layer portion OL1, and the second main surface-side outer layer portion OL2. The first lateral surface-side outer layer portion WG1 and the second lateral surface-side outer layer portion WG2 are also referred to as the W gaps.

The first lateral surface-side outer layer portion WG1 and the second lateral surface-side outer layer portion WG2 are the portion without the internal electrode layers in the lamination direction T. The first lateral surface-side outer layer portion WG1 is located on the first lateral surface S1 side, is the portion without the internal electrode in the lamination direction T, and is the portion sandwiched by the first main surface-side outer layer portion OL1 and the second main surface-side outer layer portion OL2. The first lateral surface-side outer layer portion WG1 is located on the first lateral surface S1 side, and can include a plurality of dielectric layers between the first lateral surface S1, the first main surface-side outer layer portion OL1, the second main surface-side outer layer portion OL2, and the outermost surface of the inner layer portion on the first lateral surface S1 side.

Similarly, the second lateral surface-side outer layer portion WG2 is located on the second lateral surface S2 side, is the portion without the internal electrode in the lamination direction T, and is the portion sandwiched by the first main surface-side outer layer portion OL1 and the second main surface-side outer layer portion OL2. Thus, the second lateral surface-side outer layer portion WG2 is located on the second lateral surface S2 side, and can include a plurality of dielectric layers provided between the second lateral surface S2, the first main surface-side outer layer portion OL1, the second main surface-side outer layer portion OL2, and the outermost surface of the inner layer portion on the second lateral surface S2 side.

### Internal Electrode Layers

The internal electrode layers include a plurality of first internal electrode layers 6a and a plurality of second internal electrode layers 6b. The first internal electrode layers 6a are internal electrode layers exposed at the first end surface E1. The second internal electrode layers 6b are internal electrode layers exposed at the second end surface E2.

The first internal electrode layer 6a includes a first counter electrode portion 7a opposing the second internal electrode layer 6b, and a first extension electrode portion 8a extending from the first counter electrode portion 7a to the first end surface E1 of the multilayer body 2. The end of the first extension electrode portion 8a on the first end surface E1 side extends to the surface of the first end surface E1 of the multilayer body 2. The end of the first extension electrode portion 8a extending to the first end surface E1 defines and functions as an exposed portion at the first end surface E1.

The second internal electrode layer 6b includes a second counter electrode portion 7b opposing the first internal electrode layer 6a, and a second extension electrode portion 8b extending from the second counter electrode portion 7b to the second end surface E2 of the multilayer body 2. The end of the second extension electrode portion 8b on the second end surface E2 side extends to the surface of the second end surface E2 of the multilayer body 2. The end of the second extension electrode portion 8b extending to the second end surface E2 defines and functions an exposed portion at the second end surface E2.

The shape of the first counter electrode portion 7a and the second counter electrode portion 7b is preferably rectangular or substantially rectangular, but the shape of the first counter electrode portion 7a and the second counter electrode portion 7b is not limited to any specific shape. The corners of the first counter electrode portion 7a and the second counter electrode portion 7b may be rounded. The corners of the first counter electrode portion 7a and the second counter electrode portion 7b may be diagonal. The diagonal formation implies a tapered formation.

In the first example embodiment, the shape of the first extension electrode portion 8a and the second extension electrode portion 8b is preferably rectangular or substantially rectangular, but is not limited to this particular shape. The shape of the first extension electrode portion 8a and the second extension electrode portion 8b is preferably rectangular or substantially rectangular. However, the corners of the first extension electrode portion 8a and the second extension electrode portion 8b may be rounded. The corners of the first extension electrode portion 8a and the second extension electrode portion 8b may be rounded. The diagonal formation implies a tapered formation.

The width of the first counter electrode portion 7a and the width of the first extension electrode portion 8a may be the same or substantially the same. Alternatively, one of the width of the first counter electrode portion 7a and the width of the first extension electrode portion 8a may be narrower than the other.

Similarly, the width of the second counter electrode portion 7b and the width of the second extension electrode portion 8b may be the same or substantially the same, or one may be narrower than the other. Alternatively, one of the width of the second counter electrode portion 7b and the width of the second extension electrode portion 8b may be narrower than the other.

The first internal electrode layer 6a and the second internal electrode layer 6b can be made from suitable conductive materials such as, for example, metals including Ni, Cu, Ag, Pd, Au, or alloys containing at least one of these metals, such as Ag—Pd alloy.

In the present example embodiment of the multilayer ceramic capacitor 1, the first counter electrode portion 7a and the second counter electrode portion 7b oppose each other across the inner dielectric layer 4, thus generating capacitance. This develops the capacitive characteristics of the multilayer ceramic capacitor 1.

The thickness of each of the first internal electrode layer 6a and the second internal electrode layer 6b is, for example, preferably between approximately 0.2 μm and approximately 2.0 μm inclusive. The total number of the first internal electrode layer 6a and the second internal electrode layer 6b is, for example, preferably between 15 layers and 2000 layers inclusive.

### Reduction of Step Near End Surfaces

In the present example embodiment of the multilayer ceramic capacitor 1, a second dielectric layer 5b is provided. The second dielectric layer 5b is provided to equalize the length of the multilayer body 2 in the lamination direction T.

Referring to FIG. 2, the step layer will be described. With respect to the length of the multilayer body 2 in the lamination direction T, the difference in length is preferably small between the L counter portion LF and the first and second end surface-side outer layer portions LG1, LG2. However, within the inner layer range IL, the inner dielectric layers 4 are provided between the first internal electrode layer 6a and the second internal electrode layer 6b within the L counter portion LF; however, the first end surface-side outer layer portion LG1 and the second end surface-side outer layer portion LG2 include the spots without the first internal electrode layer 6a, the second internal electrode layer 6b, and the inner dielectric layer 4; therefore, the multilayer body, which has been subjected to the stacking and pressing processes, tends to differ in length in the lamination direction T between the L counter portion LF and the first and second end surface-side outer layer portions LG1, LG2.

Within the inner layer range IL, the inner dielectric layers 4, the first internal electrode layer 6a, and the second internal electrode layer 6b are stacked in the L counter portion LF.

In contrast, only the inner dielectric layers 4 and the first internal electrode layer 6a are stacked in the first end surface-side outer layer portion LG1. The second internal electrode layer 6b is not stacked in the first end surface-side outer layer portion LG1.

Only the inner dielectric layers 4 and the second internal electrode layer 6b are stacked in the second end surface-side outer layer portion LG2. The first internal electrode layer 6a is not stacked in the second end surface-side outer layer portion LG2.

Therefore, the multilayer body, which has been subjected to the stacking and pressing processes, tends to differ in length in the lamination direction T between the L counter portion LF and the first and second end surface-side outer layer portions LG1, LG2.

In order to reduce the difference in length in the lamination direction T between the L counter portion LF and the first and second end surface-side outer layer portions LG1, LG2, additional inner dielectric layers 4 are provided in the first and second end surface-side outer layer portions LG1, LG2. The additional inner dielectric layer 4 are referred to as the second dielectric layers 5b. The dielectric layers other than the second dielectric layers 5b included in the multilayer body 2 are referred to as the first dielectric layers 5a.

The second dielectric layer 5b is provided between the end of the L counter portion LF on the first end surface E1 side and the end of the first end surface-side outer layer portion LG1 on the first end surface E1 side. The second dielectric layer 5b is also provided between the end of the L counter portion LF on the second end surface E2 side and the end of the second end surface-side outer layer portion LG2 on the second end surface E2 side.

The second dielectric layer 5b preferably includes the principal components similar to those of the first dielectric layer 5a. However, the components of the second dielectric layer 5b are not limited to this.

### Reduction of Step Near Lateral Surfaces

In the present example embodiment of the multilayer ceramic capacitor 1, the second dielectric layer 5b is also provided on the lateral surfaces. This is described based on FIG. 3. The length of the multilayer body 2 in the lamination direction T is preferably uniform not only in the length direction L but also in the width direction W. However, similar to the length direction L, in the width direction W within the inner layer range IL, the length in the lamination direction T tends to differ between the W counter portion WF and the first and second lateral surface-side outer layer portions WG1, WG2.

Within the inner layer range IL, the inner dielectric layer 4, the first internal electrode layer 6a, and the second internal electrode layer 6b are stacked in the W counter portion WF.

In contrast, the first internal electrode layer 6a and the second internal electrode layer 6b are not stacked in the first lateral surface-side outer layer portion WG1 and the second lateral surface-side outer layer portion WG2. Only the inner dielectric layer 4 is stacked in the first lateral surface-side outer layer portion WG1 and the second lateral surface-side outer layer portion WG2.

Therefore, the length in the lamination direction T tends to differ between the W counter portion WF and the first and second lateral surface-side outer layer portions WG1, WG2.

In order to reduce the difference in length in the lamination direction T between the W counter portion WF and the first and second lateral surface-side outer layer portions WG1, WG2, additional inner dielectric layers 4 are provided in the first and second lateral surface-side outer layer portions WG1, WG2. These additional inner dielectric layers 4 are the second dielectric layers 5b.

The second dielectric layer 5b is provided between the end of the first lateral surface-side outer layer portion WG1 on the first lateral surface S1 side and the end of the W counter portion WF on the first lateral surface S1 side. The second dielectric layer 5b is also provided between the end of the first lateral surface-side outer layer portion WG1 on the second lateral surface S2 side and the end of the W counter portion WF on the second lateral surface S2 side.

The present example embodiment of the multilayer ceramic capacitor 1 features specific characteristics in the concentration of additives and the particle size of ceramics in the multilayer body 2.

### Inner Layer Portion

The portion where the first internal electrode layer 6a and the second internal electrode layer 6b oppose each other is referred to as the inner layer portion 10. The inner layer portion 10 is the portion where the L counter portion LF illustrated in FIG. 2 and the W counter portion WF illustrated in FIG. 3 intersect with the inner layer range IL. The inner layer portion 10 has a rectangular or substantially rectangular parallelepiped shape. FIG. 2 illustrates the portion, where the L counter portion LF and the inner layer range IL intersect with each other, as the inner layer portion 10. FIG. 3 illustrates the portion, where the W counter portion WF and the inner layer range IL intersect with each other, as the inner layer portion 10.

### Concentration of Additives

In the LT cross-section illustrated in FIG. 2, the end of the inner layer portion 10 on the first end surface E1 side is referred to as a region R1. The end of the inner layer portion 10 on the second end surface E2 side is referred to as a region R2. The central portion of the inner layer portion 10 in the length direction L is referred to as a region R3.

The concentration of additives in the regions R1 and R2 is higher than the concentration of additives in the region R3.

The same applies to the WT cross-section. In the WT cross-section illustrated in FIG. 3, the end of the inner layer portion 10 on the first lateral surface S1 side is referred to as a region R4. The end of the inner layer portion 10 on the second lateral surface S2 side is referred to as a region R5. The central portion of the inner layer portion 10 in the width direction W is referred to as a region R6.

The concentration of additives in the regions R4 and R5 is higher than the concentration of additives in the region R6.

### Types of Additives

The additive used is preferably nickel (Ni), for example. The concentration of additives refers to the concentration of Ni. The type of additives is not limited to Ni. Examples of additives other than Ni may include, for example, Mn and Mg.

The concentration of additives at the end surface sides and the lateral surface sides of the inner layer portion 10 is higher than in the central portion of the inner layer portion 10, thus allowing for enhancement of the reliability of the multilayer ceramic capacitor 1. Specifically, when the concentration of Ni is higher at the end surface sides and the lateral surface sides of the inner layer portion 10, the firing process can maintain smaller particle sizes of the ceramic at the end surface sides and the lateral surface sides of the inner layer portion 10, thereby allowing for an increase in the number of ceramic particles within the dielectric layers. Consequently, the number of ceramic particles in the dielectric layers is increased, thereby allowing for a reduction in the voltage applied per grain boundary, thus suppressing or minimizing insulation degradation and insulation breakdown at the end surface sides and the lateral surface sides of the inner layer portion 10 where the electric field tends to concentrate.

The reliability of the described multilayer ceramic capacitor 1 is related to the particle size of the ceramics in the dielectric layers. Hereinafter, the ceramic particle size is described.

### Ceramic Particle Size

In the LT cross-section illustrated in FIG. 2, the particle size of the ceramic in the region R1 and the particle size of the ceramic in the region R2 are smaller than the particle size of the ceramic in the region R3.

Similarly, in the WT cross-section illustrated in FIG. 3, the particle size of the ceramic in the region R4 and the particle size of the ceramic in the region R5 are smaller than the particle size of the ceramic in the region R6.

The particle size of the ceramic at the end surface sides and the lateral surface sides of the inner layer portion 10 are smaller than the particle size of the ceramic in the central portion of the inner layer portion 10, thus achieving the following effects:

The ceramic particle size is reduced, thus allowing for an increase in the number of ceramic particles at the end surface sides and the lateral surface sides of the inner layer portion 10. This allows for a decrease in the voltage applied per grain boundary of ceramic particles. This consequently allows for suppression of insulation degradation and insulation breakdown at the end surface sides and the lateral surface sides of the inner layer portion 10 where the electric field tends to concentrate.

The particle size of the ceramic on the end surface sides and the lateral surface sides of the inner layer portion 10 is smaller than the particle size of the ceramic in the central portion of the inner layer portion 10, which is due to the higher concentration of additives at the end surface sides and the lateral surface sides of the inner layer portion 10 than the concentration of additives in the central portion of the inner layer portion 10.

As described previously, in the present example embodiment, the additive is Ni, for example. The presence of Ni in the first dielectric layer 5a at the end surface sides and the lateral surface sides of the inner layer portion 10 achieves the following effects.

The inclusion of Ni allows maintaining a smaller ceramic particle size at the end surface sides and the lateral surface sides of the inner layer portion 10. Consequently, the number of ceramic particles in the first dielectric layer 5a can be increased at the end surface sides and the lateral surface sides of the inner layer portion 10. The number of ceramic particles in the first dielectric layer 5a at the end surface sides and the lateral surface sides of the inner layer portion 10 is increased, thereby allowing for a reduction in the voltage applied per grain boundary. This consequently allows for suppression of insulation degradation and insulation breakdown in the first dielectric layer 5a at the end surface sides and the lateral surface sides of the inner layer portion 10 where the electric field tends to concentrate.

The ratio of the concentration of additives in the regions R1, R2, R4, and R5 of the inner layer portion 10 to the concentration of additives in the regions R3 and R6 of the inner layer portion 10 is between about 100.1 mol % and about 103.0 mol % inclusive. If the concentration ratio is less than about 100.1 mol %, the ceramic particle size in the dielectric layer cannot be reduced, and the voltage applied per grain boundary cannot be lowered, thus failing to suppress insulation breakdown, consequently failing to enhance reliability. If the concentration ratio exceeds about 103.0%, an excess of acceptors in the dielectric layer causes an excessive generation of oxygen vacancies, which accelerates the degradation of electric field strength, and leads to insulation breakdown, thus failing to enhance reliability.

The particle sizes of the ceramic in the regions R1, R2, R4, and R5 of the inner layer portion 10 are, for example, about 10% to about 40% smaller than the particle sizes of the ceramic in in the regions R3 and R6 of the inner layer portion 10. If the reduction in particle size is less than about 10%, the reliability improvement effect from reducing the ceramic particle size cannot be achieved. If the reduction in particle size exceeds about 40%, the particle size becomes too small, and the permittivity (εᵣ) is reduced, thus the desired capacitance cannot be achieved.

FIG. 4 illustrates the cross-section along the line III-III in FIG. 1. FIG. 4 illustrates the LW cross-section of the multilayer ceramic capacitor 1. The distribution of the particle sizes of the ceramic on the LW plane of the multilayer ceramic capacitor 1 will be described.

### Region R2

The line L1 illustrated in FIG. 4 marks, for example, a position about 60 μm from the end of the inner layer portion 10 on the second end surface E2 side towards the first end surface E1. Thus, the distance D1 illustrated in FIG. 4 is, for example, about 60 μm. In the inner layer portion 10, the region between the end of the inner layer portion 10 on the second end surface E2 side and the line L1 is the region R2. The end of the inner layer portion 10 on the second end surface E2 side serves as the interface between the inner layer portion 10 and the second dielectric layer 5b.

The line L2 illustrated in FIG. 4 marks, for example, a position about 60 μm from the end of the inner layer portion 10 on the second lateral surface S2 side towards the first lateral surface S1. Thus, the distance D2 illustrated in FIG. 4 is, for example, about 60 μm. In the inner layer portion 10, the region between the end of the inner layer portion 10 on the second lateral surface S2 side and the line L2 is the region R5. The end of the inner layer portion 10 on the second lateral surface S2 side serves as the interface between the inner layer portion 10 and the second dielectric layer 5b.

### Regions R2 and R5

The regions at the ends of the inner layer portion 10, specifically the regions R2 and R5, have been described above. The same applies to the regions R1 and R4. The region R1 is the region from the end of the inner layer portion 10 on the first end surface E1 side to a line marking, for example, a position about 60 μm towards the second end surface E2. The region R4 is the region from the end of the inner layer portion 10 on the first lateral surface S1 side to a line marking, for example, a position about 60 μm towards the second lateral surface S2.

The line L3 illustrated in FIG. 4 is the centerline of the inner layer portion 10 in the length direction L. The line L4 is the centerline of the inner layer portion 10 in the width direction W.

### Region R)

In the inner layer portion 10, the region with, for example, about 60 μm length in the length direction L, centered around the line L3, is the region R3. The distance D3 illustrated in FIG. 4 is 60 μm.

### Region R6

In the inner layer portion 10, the region, for example, with about 60 μm length in the width direction W, centered around the line L4, is the region R6. The distance D4 illustrated in FIG. 4 is, for example, about 60 μm.

As previously described, in the length direction L, the concentration of additives in the region R2 is higher than the concentration of additives in the region R3. The particle size of the ceramic in the region R2 is smaller than the particle size of the ceramic in the region R3.

In the width direction W, the concentration of additives in the region R5 is higher than the concentration of additives in the region R6. The particle size of the ceramic in the region R5 is smaller than the particle size of the ceramic in the region R6.

Here, the region where the regions R2 and R5 overlap is referred to as a region R7. The particle size of the ceramic in the region R7 is smaller than the particle sizes of the ceramic in the regions R2 and R5. In the region R7, the ceramic particle size is the smallest, thus the number of ceramic particles within the dielectric layer is the largest, thereby allowing for formation of a large number of grain boundaries. The number of ceramic particles within the dielectric layer is increased, thereby allowing for a reduction in the voltage applied per grain boundary, thus allowing suppression of insulation degradation and insulation breakdown at the intersections of the end surface sides and the lateral surface-side ends of the inner layer portion 10 where the electric field tends to concentrate.

Some ends of the inner layer portion 10 have been described above as examples. The same applies to the other ends of the inner layer portion 10. The ceramic particle size and other aspects will be further described later.

### External Electrodes

Next, the external electrodes will be described. The external electrodes include the first external electrode 20a and the second external electrode 20b. The first external electrode 20a is connected to the first internal electrode layer 6a. The first external electrode 20a is also provided over the first end surface E1, covering portion of the first main surface M1 and portion of the second main surface M2, as well as portion of the first lateral surface S1 and portion of the second lateral surface S2.

The second external electrode 20b is connected to the second internal electrode layer 6b. The second external electrode 20b is also provided over the second end surface E2, covering portion of the first main surface M1 and portion of the second main surface M2, as well as portion of the first lateral surface S1 and portion of the second lateral surface S2.

The first external electrode 20a and the second external electrode 20b preferably include a base electrode layer and a plated layer. The base electrode layer can include at least one selected from a fired layer, an electrically conductive resin layer, or a thin film layer. The electrically conductive resin layer can also be provided separately from the base electrode layer. The following describes an example of a configuration including a fired layer as the base electrode layer, and further including an electrically conductive resin layer separately from the base electrode layer.

The first external electrode 20a includes a first base electrode layer 21a, a first electrically conductive resin layer 22a, a first lower plated layer 23a, and a first upper plated layer 24a. The second external electrode 20b includes a second base electrode layer 21b, a second electrically conductive resin layer 22b, a second lower plated layer 23b, and a second upper plated layer 24b.

The first base electrode layer 21a and the second base electrode layer 21b are layers that include electrically conductive metals and glass components. The first electrically conductive resin layer 22a and the second electrically conductive resin layer 22b are layers including a thermosetting resin and do not includemetal components. The first lower plated layer 23a and the second lower plated layer 23b can be, for example, Ni plated layers. The first upper plated layer 24a and the second upper plated layer 24b can be, for example, Sn plated layers. Each of these layers will be described in sequence below.

### Base Electrode Layer

The base electrode layer preferably includes the first base electrode layer 21a and the second base electrode layer 21b. The first base electrode layer 21a is provided over the first end surface E1, covering portion of the first main surface M1 and portion of the second main surface M2, as well as portion of the first lateral surface S1 and portion of the second lateral surface S2. The second base electrode layer 21b is provided over the second end surface E2, covering portion of the first main surface M1 and portion of the second main surface M2, as well as portion of the first lateral surface S1 and portion of the second lateral surface S2.

The first base electrode layer 21a and the second base electrode layer 21b include electrically conductive metals and glass components. The electrically conductive metals include, for example, at least one of Cu, Ni, Ag, Pd, Ag—Pd alloy, Au, or others. The glass components include, for example, at least one of B, Si, Ba, Mg, Al, Li, or others.

The first base electrode layer 21a and the second base electrode layer 21b may each be provided in a plurality of layers. The first base electrode layer 21a and the second base electrode layer 21b may be created by applying and firing an electrically conductive paste containing glass components and metals on the multilayer body. The firing may occur simultaneously with firing the internal electrode layers, or after firing the internal electrode layers. In the case of simultaneously firing the internal electrode layer and the dielectric layer, the base electrode layer is preferably formed by firing by adding dielectric material instead of glass components. Thus, the first base electrode layer 21a and the second base electrode layer 21b are configured as fired layers.

The thickness of the first base electrode layer 21a at the central portion in the lamination direction T located at the first end surface E1 is, for example, preferably between approximately 10 μm and approximately 150 μm inclusive. Similarly, the thickness of the second base electrode layer 21b at the central portion in the lamination direction T located at the second end surface E2 is, for example, preferably between approximately 10 μm and approximately 150 μm inclusive.

When the first base electrode layer 21a and the second base electrode layer 21b are provided on the first main surface M1 and the second main surface M2 as well as on the first lateral surface S1 and the second lateral surface S2, the thickness of the first base electrode layer 21a or the second base electrode layer 21b at the central portion of the first base electrode layer 21a or the second base electrode layer 21b in the length direction L, located at the first main surface M1 and the second main surface M2 as well as on the first lateral surface S1 and the second lateral surface S2, for is, example, preferably between approximately 5 μm and approximately 50 μm inclusive.

When the base electrode layer is a thin film layer, the thin film layer can be formed by thin film deposition methods such as sputtering or vapor deposition. The formed thin film layer is, for example, preferably a layer of deposited metal particles with the thickness of about 1 μm or lower.

### Electrically Conductive Resin Layer

An electrically conductive resin layer is provided on the base electrode layer. The electrically conductive resin layer includes resin components and metal components. The electrically conductive resin layer includes the first electrically conductive resin layer 22a and the second electrically conductive resin layer 22b. The first electrically conductive resin layer 22a and the second electrically conductive resin layer 22b preferably include, for example, a thermosetting resin as the resin component. Therefore, the first electrically conductive resin layer 22a and the second electrically conductive resin layer 22b are more flexible than the base electrode layer. This is because the base electrode layer include plating films or a fired mixture of metal and glass components.

Thus, even if physical shock is applied to the multilayer ceramic capacitor 1 due to bending stress on the mounting board, or if thermal cycle-induced shock is applied to the multilayer ceramic capacitor 1, cracks can be prevented from occurring in the multilayer ceramic capacitor 1. This is because the electrically conductive resin layer functions as a buffer layer.

Specific examples of thermosetting resins included in the electrically conductive resin layer include well-known thermosetting resins such as epoxy resin, phenolic resin, urethane resin, silicone resin, and polyimide resin. Among these, epoxy resin is one of the most suitable resins. Epoxy resin is excellent in heat resistance, moisture resistance, and adhesion properties.

The first electrically conductive resin layer 22a is provided on the first base electrode layer 21a. The first electrically conductive resin layer 22a is provided so as to cover the first base electrode layer 21a. The ends of the first electrically conductive resin layer 22a is preferably in contact with the multilayer body 2. Similarly, the second electrically conductive resin layer 22b is provided on the second base electrode layer 21b. The second electrically conductive resin layer 22b is provided so as to cover the second base electrode layer 21b. The ends of the second electrically conductive resin layer 22b is preferably in contact with the multilayer body 2.

The metal components included in the first electrically conductive resin layer 22a and the second electrically conductive resin layer 22b can be, for example, Ag, Cu, Ni, Sn, Bi, or alloys including these metals. The metal components are, for example, preferably in the form of metal fillers. If the metal components are metal powders, for example, metal powders coated with Sn, Ni, or Cu on the surface of the metal powders can be used. When the metal powders coated with Sn, N, or Cu on the surface of the metal powders are used, for example, metal powders of Ag, Cu, Ni, Sn, Bi, or their alloys are preferably used. Particularly, the metal components preferably include Ag. Ag can be used as pure Ag, or as an alloy containing Ag, or even as metal powder coated with Ag.

When the metal powder coated with Ag on the surface of the metal powder is used, for example, metal powders of Cu, Ni, Sn, Bi, or their alloy powders are preferably used. Using Ag as a metal filler offers the following advantages.

Ag has the lowest specific resistance among metals. This allows for formation of electrodes with low electrical resistance. As a precious metal, Ag is less prone to oxidation. This enhances the durability of the electrically conductive resin layer. By using Ag as a metal filler, the characteristics of Ag can be maintained, while opting for a more cost-effective base metal.

The shape of the metal fillers included in the first electrically conductive resin layer 22a and the second electrically conductive resin layer 22b is not particularly limited. The metal fillers may be spherical or flattened. The metal fillers may be a mixture of spherical and flattened metal powders.

The average particle size of the metal fillers included in the first electrically conductive resin layer 22a and the second electrically conductive resin layer 22b is not particularly limited. The average particle size of the metal fillers can be, for example, between about 0.3 μm and about 10 μm inclusive. The average particle size of the metal fillers in the electrically conductive resin layer can be determined using the laser diffraction particle size measurement method (preferably based on ISO 13320). This method of determining the average particle size can be applied regardless of the shape of the fillers.

The metal fillers included in the first electrically conductive resin layer 22a and the second electrically conductive resin of the layer 22b primarily ensure the conductivity electrically conductive resin layer. Specifically, contact between the metal fillers creates a conductive pathway within the electrically conductive resin layer.

The resins used in the first electrically conductive resin layer 22a and the second electrically conductive resin layer 22b can include various well-known thermosetting resins such as, for example, epoxy resin, phenoxy resin, phenolic resin, urethane resin, silicone resin, and polyimide resin. Among these, epoxy resin is one of the most suitable resin due to excellent heat resistance, moisture resistance, and adhesion properties.

The first electrically conductive resin layer 22a and the second electrically conductive resin layer 22b preferably include a hardener along with the thermosetting resin. When using epoxy resin as the base resin, various well-known compounds such as phenolic, amine, anhydride, imidazole, active ester, and amide-imide systems can be used as the hardener.

The metal content in the first electrically conductive resin layer 22a is, for example, preferably between about 35 vmol % and about 75 vmol % inclusive of the total volume of the first electrically conductive resin layer 22a. Similarly, the metal content in the second electrically conductive resin layer 22b is, for example, preferably between about 35 vmol % and about 75 vmol % inclusive of the total volume of the second electrically conductive resin layer 22b.

The resin content in the first electrically conductive resin layer 22a is, for example, preferably between about 25 vmol % and about 65 vmol % inclusive of the total volume of the first electrically conductive resin layer 22a. Similarly, the resin content in the second electrically conductive resin layer 22b is, for example, preferably between about 25 vmol % and about 65 vmol % inclusive of the total volume of the second electrically conductive resin layer 22b.

With respect to the first electrically conductive resin layer 22a or the second electrically conductive resin layer 22b located at the first end surface E1 or the second end surface E2, the thickness of the first electrically conductive resin layer 22a or the second electrically conductive resin layer 22b located at the central portion in the lamination direction T is, for example, preferably between approximately 10 μm and approximately 200 μm inclusive.

When the first electrically conductive resin layer 22a and the second electrically conductive resin layer 22b are also provided on the first main surface M1 and the second main surface M2 as well as on the first lateral surface S1 and the second lateral surface S2, the thickness of the first electrically conductive resin layer 22a and the second electrically conductive resin layer 22b at the central portion in the length direction L, provided on the first main surface M1 and the second main surface M2 as well as on the first lateral surface S1 and the second lateral surface S2, is, for example, preferably between approximately 10 μm and approximately 200 μm inclusive.

### Plated Layers

The plated layers will be described. The plated layers, as mentioned previously, include a lower plated layer and an upper plated layer. In other words, the plated layers include two layers. However, the plated layers may be either a single layer or a plurality of layers.

### Lower Plated Layer

The lower plated layer is provided on top of the electrically conductive resin layer. The lower plated layer covers at least portion of the electrically conductive resin layer. The lower plated layer includes the first lower plated layer 23a and the second lower plated layer 23b. The first lower plated layer 23a is provided on top of the first electrically conductive resin layer 22a. The second lower plated layer 23b is provided on top of the second electrically conductive resin layer 22b.

The first lower plated layer 23a and the second lower plated layer 23b can be Ni plated layers. Using Ni plated layers for the lower plated layers can prevent the base electrode layer from being eroded by solder during the mounting of the multilayer ceramic capacitor 1.

### Upper Plated Layer

The upper plated layer is provided on top of the lower plated layer. The upper plated layer covers at least portion of the lower plated layer. The upper plated layer includes the first upper plated layer 24a and the second upper plated layer 24b. The first upper plated layer 24a is provided on top of the first lower plated layer 23a. The second upper plated layer 24b is provided on top of the second lower plated layer 23b.

The first upper plated layer 24a and the second upper plated layer 24b can be, for example, Sn plated layers. Sn plated layers is excellent in solder wettability. Therefore, using Sn plated layers for the upper plated layers makes it easier to mount the multilayer ceramic capacitor 1 on boards or similar platforms.

The metals used for the lower and upper plated layers are not limited to the examples described above. The plated layers, including the lower and upper plated layers, may include at least one selected from metals such as, for example, Cu, Ni, Ag, Pd, Au, Sn, and alloys such as Ag—Pd alloy.

The thickness of each plated layer is, for example, preferably between about 2 μm and about 15 μm inclusive.

External electrodes can be solely formed with plated layers, without a base electrode layer. The following describes a structure where only plated layers are provided without a base electrode layer.

Each of the first external electrode 20a and the second external electrode 20b is directly formed as plated layers on the surface of the multilayer body 2. That is, the multilayer ceramic capacitor 1 may include a structure containing a plated layer that is electrically connected to either the first internal electrode layer 6a or the second internal electrode layer 6b. When the external electrodes are structured in this manner, a catalyst may be applied to the surface of multilayer body 2 as a pretreatment before forming the plated layers.

The plated layers preferably include a lower plated electrode formed on the surface of multilayer body 2 and an upper plated electrode formed on the surface of the lower plated electrode. In this case, both the lower plated electrode and the upper plated electrode preferably include at least one metal or an alloy including the metal, selected from Cu, Ni, Sn, Pb, Au, Ag, Pd, Bi, or Zn, for example.

The lower plated electrode is, for example, preferably formed using Ni, which has solder barrier properties. The upper plated electrode is preferably formed using materials such as, for example, Sn or Au, which offer good solder wettability.

For example, in the case where the first internal electrode layer and the second internal electrode layer are formed using Ni, the lower plated electrode is preferably formed using Cu, which has good bonding properties with Ni. The upper plated electrode may be formed as needed, and the first external electrode 20a and the second external electrode 20b may include only of the lower plated electrode.

As for the plated layers, the upper plated electrode may be formed as the outermost layer, or another plated electrode may be formed on the surface of the upper plated electrode. When providing plated layers without a base electrode layer, the thickness of each of the plated layers is, for example, preferably between about 1 μm and about 15 μm inclusive. The plated layer preferably does not include glass. The metal content per unit volume of the plated layer is, for example, preferably at least about 99% by volume.

The dimensions of the multilayer ceramic capacitor 1 are not particularly limited. The dimension of the multilayer ceramic capacitor 1, including the multilayer body 2 and the external electrodes, in the length direction L is referred to as the L dimension. The L dimension is, for example, preferably between about 0.2 mm and about 10 mm inclusive. The dimension of the multilayer ceramic capacitor 1, including the multilayer body 2 and the external electrodes, in the lamination direction T is referred to as the T dimension. The T dimension is, for example, preferably between about 1 mm and about 0.5 mm inclusive. The dimension of the multilayer ceramic capacitor 1, including the multilayer body 2 and the external electrodes, in the width direction W is referred to as the W dimension. The W dimension is, for example, preferably between about 0.1 mm and about 10 mm inclusive.

Method of Manufacturing Multilayer Ceramic Capacitor of First Embodiment

an example embodiment of a method of manufacturing the multilayer ceramic capacitor 1 will be described.

(1) Prepare dielectric sheets and electrically conductive paste for internal electrode layers. The dielectric sheets and the electrically conductive paste for internal electrode layers include binders and solvents. Known organic binders and solvents can be used for these binders and solvents.

(2) Print the electrically conductive paste for internal electrode layers onto the dielectric sheets in a predetermined pattern to form the internal electrode layer patterns. Printing can be done using methods such as screen printing or gravure printing.

(3) Stack a predetermined number of dielectric sheets for outer layer portions. The internal electrode layer patterns are not printed on the dielectric sheets for outer layer portions. The dielectric sheets with printed internal electrode layer patterns are successively stacked thereon. Further, a predetermined number of dielectric sheets for outer layer portions are stacked thereon. This process creates a multilayer sheet.

Next, the second dielectric layer 5b to reduce step differences will be described. The dielectric paste serving as the second dielectric layer 5b is referred to as the step reduction paste.

The step reduction paste is applied to the region around the internal electrode layer patterns, in the dielectric sheets where the internal electrode layer patterns are formed by printing the electrically conductive paste for internal electrode layers. Specifically, the step reduction paste is applied to portions where the internal electrode layer patterns are not formed. The step reduction paste is used to eliminate the step differences between the internal electrode layer patterns and the surrounding regions. The step reduction paste can be applied to partly overlap the region around the internal electrode layer patterns. In this case, the overlap width can be approximately 50 μm, for example. The step reduction paste can also be applied so as to form a gap with the internal electrode layer patterns. In this case, the gap width can be approximately 50 μm, for example.

When printing the step reduction paste, for example, the amount overlapping the internal electrode layers, i.e., the overlap amount, is-30 μm in the length direction L, about +20 μm in the width direction W, and the thickness being approximately 50% of the thickness of the internal electrode layer pattern or the thickness of Ni. When printing the step reduction paste on the dielectric sheet first, then printing the paste for the internal electrode layer, for example, the amount overlapping the second dielectric layer 5b can be about-30 μm in the length direction L, about +20 μm in the width direction W, and the thickness being approximately 50% of the thickness of the internal electrode layer pattern or the thickness of Ni.

The same ceramic paste used for the dielectric sheets or a different material may also be used for the step reduction paste. The step reduction paste contains a higher amount of Ni than the ceramic paste used for the dielectric sheets. The increased amount of Ni added in the step reduction paste causes diffusion of Ni into the dielectric sheet. Ni can be added by adding Ni powder to the paste while preparing the step reduction paste. Ni can also be added by increasing the amount of Ni added while preparing the raw material. After printing the step reduction paste on the dielectric sheet, for example, Ni paste can be further printed on the step reduction paste.

(4) Press the multilayer sheets in the lamination direction to create a multilayer block. The pressing can be done using, for example, hydrostatic pressing.

(5) Cut the multilayer block to a predetermined size. This process produces the multilayer chips. In this case, the corners and edge lines of the multilayer chips may be rounded. The rounding can be done through barrel polishing, for instance.

(6) Fire the multilayer chips. This process produces the multilayer body. The firing temperature is, for example, preferably between about 900° C. and about 1200° C. inclusive. The firing temperature can be adjusted based on the materials of the dielectric and the internal electrode layers. The grain growth is promoted through this process of stacking, high-temperature degreasing, firing, and annealing. However, the grain growth is suppressed at the end surface sides and the lateral surface sides of the inner layer portion 10 due to a higher solid solution amount of Ni.

Next, external electrodes are provided on the multilayer body.

(7) Apply an electrically conductive paste on both end surfaces of the multilayer body to form the base electrode layers. In the present example embodiment, a fired layer is formed as a base electrode layer. When forming a fired layer, the electrically conductive paste is applied to a predetermined position of the multilayer body. The electrically conductive paste contains glass components and metal. The application can be done, for example, by dipping. After application, a firing treatment is performed to form the base electrode layer. The temperature for this firing treatment is, for example, preferably between about 700° C. and about 900° C. inclusive.

(8) Form the electrically conductive resin layer on the base electrode layer. As a method of forming the electrically conductive resin layer, first of all, a conductive resin paste containing resin and metal components is prepared. This conductive resin paste is applied onto the base electrode layer. This application can be done through a dipping method. After application, a heat treatment is performed at, for example, a temperature between about 200° C. and about 550° C. inclusive. This heat treatment cures the resin. This process defines the conductive electrode layer. The atmosphere during the heat treatment is preferably a nitrogen gas environment. The oxygen concentration is, for example, preferably kept below 100 ppm in order to prevent the resin from scattering and prevent oxidation of various metal components.

(9) After forming the electrically conductive resin layer, Ni plated layers, defining and functioning as the first lower plated layer and the second lower plated layer, are formed on the surface of the electrically conductive resin layer. Electroplating can be employed to form the first Ni plated layer and the second Ni plated layer. Barrel plating is preferably used for the plating method.

(10) In the present example embodiment, the Sn plated layer is further formed on the Ni plated layer. Specifically, the first Sn plated layer is formed on the first Ni plated layer, and the second Sn plated layer is formed on the second Ni plated layer. This improves wettability of the solder used for mounting the multilayer ceramic capacitor 1 onto a board. This allows for easily mounting the multilayer ceramic capacitor 1 onto the board. The Sn plated layer can also be formed using electroplating. Barrel plating is, for example, preferably used for the plating method.

As described above, in the present example embodiment, a material with a higher amount of Ni is used in the step reduction paste, whereby the concentration of additives at the ends of the inner layer portion 10 is made higher than the concentration of additives at the central portion of the inner layer portion 10.

### Modified Example

However, the method of increasing the concentration of additives at the ends of the inner layer portion 10 compared to the central position of the inner layer portion 10 is not limited to the method using the step reduction paste. Even in the case without using the step reduction paste, the concentration of additives at the ends of the inner layer portion 10 can be made higher than the concentration of additives at the central portion of the inner layer portion 10. The case without using the step reduction paste corresponds to the case where the second dielectric layer 5b is not provided b.

As a method in the case where the second dielectric layer 5b is not provided, for instance, additives or materials containing additives can be applied to a region where the step reduction paste is printed on the dielectric sheet. Additives or materials containing additives are applied around the internal electrode layer patterns on the dielectric sheet, whereby the concentration of additives at the ends of the inner layer portion 10 can be made higher than the concentration of additives at the central portion of the inner layer portion 10.

The provision of the second dielectric layer 5b is not limited to both the vicinity of the end surfaces and the vicinity of the lateral surfaces. The second dielectric layer 5b can be provided in either the vicinity of the end surfaces or the vicinity of the lateral surfaces. In this case, for the portions where the second dielectric layer 5b is not provided, additives or materials containing additives are applied to the corresponding portions of the dielectric sheet. As a result, the concentration of additives at the ends of the inner layer portion 10 can be made higher than the concentration of additives at the central portion of the inner layer portion 10.

### Second Example Embodiment

The following describes a second example embodiment of the multilayer ceramic capacitor 1. The following description primarily covers aspects that differ from the first example embodiment. The multilayer ceramic capacitor 1 of the second example embodiment preferably differs from the multilayer ceramic capacitor 1 of the first example embodiment in that the lateral surface-side outer layer portion is formed of a dielectric sheet for the lateral surface-side outer layer portion. In order to distinguish from the lateral surface-side outer layer portion of the first example embodiment, in the second example embodiment, the first lateral surface-side outer layer portion WG1 is referred to as the first lateral surface-side outer layer portion 30a, and the second lateral surface-side outer layer portion WG2 is referred to as the second lateral surface-side outer layer portion 30b.

FIG. 5 is a view in the second example embodiment, corresponding to the cross-sectional view along the line II-II in FIG. 1. As illustrated in FIG. 5, the multilayer body 2 includes a multilayer body core portion 40, the first lateral surface-side outer layer portion 30a, and the second lateral surface-side outer layer portion 30b. The multilayer body core portion 40 corresponds to the W counter portion WF in the multilayer body 2. In the width direction W, the first lateral surface-side outer layer portion 30a and the second lateral surface-side outer layer portion 30b are provided so as to sandwich the multilayer body core portion 40.

FIG. 6 is a view illustrating an outline of the multilayer body core portion 40. The first internal electrode layer 6a and the second internal electrode layer 6b are exposed at both end surfaces of the multilayer body core portion 40 in the width direction W.

The first lateral surface-side outer layer portion 30a and the second lateral surface-side outer layer portion 30b include a plurality of dielectric layers for the lateral surface-side outer layer portions. Specifically, as illustrated in FIG. 5, the first lateral surface-side outer layer portion 30a includes a first outer layer 32a provided on the first lateral surface S1 side, and a first inner layer 31a provided on the multilayer body core portion 40 side. The second lateral surface-side outer layer portion 30b includes a second outer layer 32b provided on the second lateral surface S2 side, and a second inner layer 31b provided on the multilayer body core portion 40 side.

Since the first outer layer 32a and the first inner layer 31a differ in sinterability, structure and the interface between the layers can be confirmed by observation with an optical microscope in a dark field. Since the second outer layer 32b and the second inner layer 31b differ in sinterability, the bilayer structure and the interface between the layers can be confirmed by observation with an optical microscope in a dark field.

There are cases where a bilayer structure and an interface between the layers cannot be observed with an optical microscope in a dark field. In such cases, the outer 80% region of the first lateral surface-side outer layer portion 30a is designated as the first outer layer 32a, and the regions other than the first outer layer 32a are designated as the first inner layer 31a. Similarly, the outer 80% region of the second lateral surface-side outer layer portion 30b is designated as the second outer layer 32b, and the regions other than the second outer layer 32b are designated as the second inner layer 31b.

The lateral surface-side outer layer portion can be composed of a dielectric material with a perovskite structure, such as barium titanate (BaTiO₃). The molar ratio of Si to Ti in the lateral surface-side outer layer portion is, for example, preferably between about 1.0 and about 7.0 inclusive.

The dimension of the lateral surface-side outer layer portion along the width direction W is, for example, preferably between about 5 μm and about 40 μm inclusive.

The inner layer of the lateral surface-side outer layer portion includes, for example, additives at a higher concentration than the outer layer. The content of Si in the outer layer of the lateral surface-side outer layer portion is preferably higher than the content of Si in the inner layer. The content of Ni in the outer layer of the lateral surface-side outer layer portion is preferably lower than the content of Ni in the inner layer.

In the present example embodiment, there is little variation in the position of the ends of the internal electrode layers on the first lateral surface S1 side and the second lateral surface S2 side of the inner layer portion 10. For example, with respect to the positions of the ends of the first internal electrode layer 6a and the second internal electrode layer 6b on the first lateral surface S1 side in the width direction W, the difference between the position closest to the first lateral surface S1 and the position of the internal electrode layer farthest from the first lateral surface S1 is, for example, about 5 μm or less. Similarly, the difference between the distance closest to the second lateral surface S2 and the distance farthest from the second lateral surface S2 is, for example, about 5 μm or less.

### Method of Manufacturing Multilayer Ceramic Capacitor of Second Embodiment

The method of manufacturing the multilayer ceramic capacitor 1 of the second example embodiment will be described below, primarily focusing on the differences from the method in the first example embodiment.

The same procedures as Steps (1) to (4) in the manufacturing method in the first example embodiment can preferably be used.

(5) Cut the multilayer block such that the electrically conductive paste corresponding to the internal electrode layers is exposed at both sides in the width direction W. Before stacking, the electrically conductive paste for the internal electrode layers is printed on the dielectric sheets in a pattern that allows such cutting.

(6) Produce dielectric sheets for the lateral surface-side outer layer portion. Specifically, a perovskite compound containing Ba and Ti is prepared as the dielectric material. At least one type of additive such as, for example, Si, Mg, Ni, and Ba is added to the dielectric powder obtained from this dielectric material. The dielectric powder is mixed with binder resin, organic solvent, plasticizer, and dispersant in the predetermined ratio. This process produces a ceramic slurry.

The solvent included in the ceramic slurry defining and functioning as the inner layer of the lateral surface-side outer layer portion is selected appropriately to prevent dissolution of the dielectric sheet for the outer layer. This dielectric sheet for the inner layer serves a role in bonding with the multilayer chips.

The Ni content in the additives included in the inner layer is preferably higher than the Ni content in the outer layer.

(7) Apply the prepared ceramic slurry, which will serve as the outer layer, to the surface of a resin film, followed by drying. As a result, a dielectric sheet for the outer layer is obtained.

(8) Apply the prepared ceramic slurry, which will serve as the inner layer, to the surface of the dielectric sheet for the outer layer, followed by drying. As a result, a dielectric sheet for the inner layer portion is obtained. In this manner, a dielectric sheet for the lateral surface-side outer layer portion with a bilayer structure is obtained.

(9) The method for obtaining the dielectric sheet for the lateral surface-side outer layer portion with a bilayer structure, by applying and drying the dielectric sheet for the inner layer portion on the surface of the dielectric sheet for the outer layer, has been described. However, formation with methods other than the described method is also possible. For instance, a dielectric sheet for the outer layer and a dielectric sheet for the inner layer portion are separately formed in advance. Subsequently, the sheets may be bonded together to obtain a dielectric sheet for the lateral surface-side outer layer portion with a bilayer structure. The dielectric sheet for the lateral surface-side outer layer portion is not limited to two layers but may include three or more layers.

(10) Next, peel off the dielectric sheets for the lateral surface-side outer layer portion from a resin film such as a PET film. Subsequently, a dielectric sheet for the inner layer, of the peeled dielectric sheets for the lateral surface-side outer layer portion, is pressed against a multilayer chip. In this case, the dielectric sheet is pressed against one side of the multilayer chip in the width direction W. Then, the sheet is punched to form a layer that serves as the lateral surface-side outer layer portion. Similarly, the dielectric sheet for the inner layer portion is pressed against the other side of the multilayer chip where no layer for the lateral surface-side outer layer portion has been formed. Then, the sheet is punched to form a layer that serves as the lateral surface-side outer layer portion. In this case, an organic solvent that serves as an adhesive is preferably pre-applied to the lateral surfaces of the multilayer chip.

(11) After forming the layer that serves as the lateral surface-side outer layer portion, the multilayer chip is degreased under predetermined conditions in a nitrogen atmosphere. Subsequently, the multilayer chip is fired in a nitrogen-hydrogen-steam mixed atmosphere at a predetermined temperature to obtain a fired multilayer body.

(12) Form external electrodes on each of the two end surfaces of the fired multilayer body. As described above, the multilayer ceramic capacitor 1 is manufactured.

In the second example embodiment, similar to the first example embodiment, the second dielectric layer 5b for step reduction can be provided near the end surface of the multilayer body. Similar to the first example embodiment, the material composing the second dielectric layer 5b can include a higher concentration of additives.

Alternatively, in the second example embodiment, it is also possible not to provide the second dielectric layer 5b near the end surface of the multilayer body. Similar to the first example embodiment, this case can use a method of applying additives or materials containing additives to the region where the step reduction paste is printed on the dielectric sheet.

Similar to the first example embodiment, in the second example embodiment, the concentration of the additives at the ends of the inner layer portion 10 can be made higher than the concentration of additives in the central portion of the inner layer portion 10. This is due to the diffusion of additives included in the lateral surface-side outer layer portion, especially the additives included in the first inner layer 31a and the second inner layer 31b, into the dielectric layer of the inner layer portion 10.

### Measurement Method

The method of measuring the ceramic particle size will be described below.

### WT Plane

Based on FIG. 7, the measurement on the WT plane is described. FIG. 7 is a perspective view illustrating the polished inner layer portion 10. First, the polishing of the inner layer portion 10 is described. The multilayer body 2 is polished from the first end surface E1 up to, for example, a position about 60 μm from the end of the inner layer portion 10 in the length direction L. This position is indicated by the line L11. The WT cross-section at the line L11 is defined as the first cross-section 11a.

Similarly, the multilayer body 2 is polished from the second end surface E2 up to, for example, a position about 60 μm from the end of the inner layer portion 10 in the length direction L. This position is indicated by the line L12. The WT cross-section at the line L12 is defined as the second cross-section 11b.

The measurement sites in the width direction W cover: about 30 μm width to one direction from the central position of the inner layer portion 10 in the width direction W and about 30 μm width to the other direction from the central position, i.e., about 60 μm width on the central position in the width direction W; and about 60 μm width from each end of the inner layer portion 10 in the width direction W. The 60 μm width on the central position of the inner layer portion 10 in the width direction W is defined as the central portion in the width direction W.

The measurement sites in the lamination direction T cover: about 30 μm width to one direction from the central position of the inner layer portion 10 in the lamination direction T and about 30 μm width from the central position to the other direction, i.e., about 60 μm width on the central position in the lamination direction T; and about 60 μm width from each end of the inner layer portion 10 in the lamination direction T. The 60 μm width on the central position of the inner layer portion 10 in the lamination direction T is defined as the central portion in the lamination direction T.

The inner layer portion 10 is further polished from the first cross-section 11a or the second cross-section 11b. The inner layer portion 10 is polished up to the midpoint of the length of the inner layer portion 10 in the length direction L. This position is indicated by the line L13. The WT cross-section at the line L13 is defined as the third cross-section 11c.

The measurement sites for the third cross-section 11c are the same as or similar to the measurement sites for the first cross-section 11a and the second cross-section 11b.

The measurement sites defined as above are indicated as the measurement sites PW. The measurement sites PW include a total of 27 sites, with nine each provided in the first cross-section 11a, the second cross-section 11b, and the third cross-section 11c.

The size of each range measured at these measurement sites is about 60 μm in both the width direction W and the lamination direction T. In other words, each side of the squares indicated at measurement sites PW is about 60 μm in length.

### LT Plane

Based on FIG. 8, measurements on the LT plane will be described. FIG. 8 is a perspective view illustrating the polished inner layer portion 10. The measurement sites for the LT plane are defined in a manner similar to the WT plane described earlier.

The multilayer body 2 is polished from the first lateral surface S1 up to a position about 60 μm from the end of the inner layer portion 10 in the width direction W. This position is indicated by the line L21. The LT cross-section at the line L21 is defined as the fourth cross-section 12a.

Similarly, the multilayer body 2 is polished from the second lateral surface S2 up to a position about 60 μm from the end of the inner layer portion 10 in the width direction W. This position is indicated by the line L22. The LT cross-section at the line L22 is defined as the fifth cross-section 12b.

The measurement sites in the length direction L cover: about 60 μm width on the central portion of the inner layer portion 10 in the length direction L; and about 60 μm width from each end of the inner layer portion 10 in the length direction L.

The measurement sites in the lamination direction T cover: about 60 μm width on the central portion of the inner layer portion 10 in the lamination direction T; and about 60 μm width from each end of the inner layer portion 10 in the lamination direction T.

The inner layer portion 10 is further polished from the fourth cross-section 12a or the fifth cross-section 12b. The inner layer portion 10 is polished up to the midpoint of the length of the inner layer portion 10 in the width direction W. This position is indicated by the line L23. The LT cross-section at the line L23 is defined as the sixth cross-section 12c.

The measurement sites for the sixth cross-section 12c are the same as or similar to the measurement sites for the fourth cross-section 12a and the fifth cross-section 12b.

The measurement sites defined as above are indicated as the measurement sites PL. The measurement sites PL include a total of 27 sites, with nine each provided in the fourth cross-section 12a, the fifth cross-section 12b, and the sixth cross-section 12c.

The size of each range measured at the measurement sites PL is the same as or similar to that at the measurement sites PW. That is, the measured range is about 60 μm in both the length direction L and the lamination direction T. In other words, each side of the squares indicated at measurement sites PL is about 60 μm in length.

The WT plane and the LT plane have been discussed above. However, measurements can similarly be conducted on the LW plane.

Measurements can be conducted by, for example, measuring the WT plane of fifteen multilayer bodies 2 from a batch manufactured under the same or substantially the same conditions, and measuring the LT plane of fifteen multilayer bodies 2 from a batch manufactured under the same conditions.

The concentration of additives and the ceramic particle size were measured at the measurement sites, and it was confirmed that the concentration of additives at the ends of the inner layer portion 10 is higher than the concentration of additives at the central portion of the inner layer portion 10, as previously described. It was also confirmed that the particle size of the ceramic at the ends of the inner layer portion 10 is smaller than the particle size of the ceramic at the central portion of the inner layer portion 10.

The measurement of the ceramic particle size is performed as follows:

Each of the measurement sites, i.e., a cross-section of about 60 μm×about 60 μm at a predetermined location, is observed under an electron microscope. The particle sizes of the ceramic particles found by observation are averaged. The averaged size is used as the ceramic particle size.

An example of the measurement results is described based on FIGS. 9 and 10. Both FIGS. 9 and 10 correspond to the LW cross-sectional views of the multilayer body, illustrating the distribution of ceramic particle sizes.

Both FIGS. 9 and 10 illustrate the multilayer ceramic capacitor 1 of the second example embodiment. Both FIGS. 9 and 10 illustrate the area near the second end surface E2 and the second lateral surface S2 of the multilayer ceramic capacitor 1.

The difference between the multilayer ceramic capacitor 1 illustrated in FIG. 9 and the multilayer ceramic capacitor 1 illustrated in FIG. 10 is whether the second dielectric layer is present or not. The multilayer ceramic capacitor 1 illustrated in FIG. 9 includes the second dielectric layer 5b near the end surface. In contrast, the multilayer ceramic capacitor 1 illustrated in in FIG. 10 does not include the second dielectric layer 5b.

The example illustrated in FIG. 9 is described. In the example illustrated in FIG. 9, the second dielectric layer 5b is provided, as previously mentioned. Therefore, an interface based on the second dielectric layer 5b is defined in the LW cross-section illustrated in FIG. 9. The ceramic particle sizes differ across this interface. Specific description is provided below.

As illustrated in FIG. 9, the particle size is the largest in the central portion (region R6) of the inner layer portion 10. This particle size is, for example, approximately 160 nm.

The next largest particle size is found within a range of about 60 μm from the interface between the inner layer portion 10 and the second end surface-side outer layer portion LG2 towards the inner layer portion 10 side (region R2). The particle size in the region R2 is approximately about 136 nm.

The next largest particle size is found within a range of about 60 μm from the interface between the inner layer portion 10 and the second lateral surface-side outer layer portion 30b towards the inner layer portion 10 side (region R5). The particle size in the region R5 is approximately about 100 nm.

The smallest particle size is found in the region R7, where the regions R2 and R5 overlap. The particle size in the region R7 is approximately about 82 nm.

Thus, the particle sizes of the ceramic in the inner layer portion 10 are in the following order:
Region R6>region R2>region R5>region R7.

Outside the inner layer portion 10, the particle sizes are as follows:

The particle size is approximately 120 nm in the second end surface-side outer layer portion LG2 where the second dielectric layer 5b is provided. The particle size is approximately about 80 nm in the second lateral surface-side outer layer portion 30b.

Next, the example illustrated in FIG. 10 is described. The second dielectric layer 5b is not provided in the example illustrated in FIG. 10. Therefore, the particle size in the region R2 is equivalent to the particle size in the region R6. This is because there is no diffusion of additives from the second dielectric layer 5b.

However, the particle size in the region R5 is smaller than the particle size in the region R6, similar to the example illustrated in FIG. 9. In the example illustrated in FIG. 10, similar to the example illustrated in FIG. 9, this is due to the diffusion of additives included in the second lateral surface-side outer layer portion 30b.

Outside the inner layer portion 10, the particle size in the second end surface-side outer layer portion LG2 is approximately 160 nm. This is equivalent to the particle size in the region R6. This is because the concentration of additives does not differ between the inner layer portion 10 and the second end surface-side outer layer portion LG2, since the second dielectric layer 5b is not provided in the example illustrated in FIG. 10.

The multilayer ceramic capacitor 1 of the present invention optimizes the content of additives at the ends of the inner layer portion 10, and the particle size of the ceramic at the ends of the inner layer portion 10. Therefore, the insulation resistance at the ends of the inner layer portion 10 is increased, compared to the conventional structure of the multilayer ceramic capacitor 1 using the step reduction ceramic paste layers without adjusted additive concentrations. As a result, the multilayer ceramic capacitor 1 with high reliability can be provided. The particle size of the ceramic at the ends of the inner layer portion 10 is varied, thereby allowing for enhancement of the reliability of the multilayer ceramic capacitor 1.

The reasons why the insulation resistance is increased by optimizing the concentration of additives and the ceramic particle size are as follows. For example, Ni is added as an additive, thereby allowing smaller particle sizes of the ceramic within the dielectric layers during the firing of the multilayer chips to be maintained. This allows for an increase in the number of ceramic particles within the dielectric layers. The number of ceramic particles within the dielectric layers is increased, thereby allowing for a reduction in the voltage applied per grain boundary. As a result, the occurrence of insulation deterioration and insulation breakdown at the ends, where the electric field is prone to concentrate, can be reduced or prevented.

In the example embodiment of the multilayer ceramic capacitor 1, the concentration of additives at the end surface sides and lateral surface face sides of the inner layer portion 10 is higher than the concentration of additives in the central portion of the inner layer portion 10. The particle size of the ceramic at the ends of the inner layer portion 10 is smaller than the particle size of the ceramic in the central portion of the inner layer portion 10. Therefore, the occurrence of insulation deterioration and insulation breakdown at the ends of the inner layer portion 10 can be further reduced or prevented.

While the example embodiments of the present invention have been described above, it should be understood that the present invention is not limited to these example embodiments, and various modifications and alterations can be made.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer ceramic electronic component, comprising:
a multilayer body including stacked dielectric layers, and first and second internal electrode layers stacked on the dielectric layers, the multilayer body including first and second main surfaces on opposite sides in a lamination direction, first and second end surfaces on opposite sides in a length direction orthogonal to the lamination direction, and first and second lateral surfaces on opposite sides in a width direction orthogonal to both the lamination direction and the length direction;
a first external electrode on the first end surface; and
a second external electrode on the second end surface; wherein
the first internal electrode layers are electrically connected to the first external electrode;
the plurality of second internal electrode layers are electrically connected to the second external electrode;
the multilayer body includes an inner layer portion where the first and second internal electrode layers oppose each other;
a particle size of ceramic included on a first lateral surface side of the inner layer portion is smaller than a particle size of the ceramic included in a central portion of the inner layer portion in the width direction;
a particle size of the ceramic included on a second lateral surface side of the inner layer portion is smaller than a particle size of the ceramic included in the central portion of the inner layer portion in the width direction;
a particle size of the ceramic included at an end of each of the second internal electrode layers on a first end surface side of the inner layer portion is smaller than a particle size of the ceramic included in the central portion of the inner layer portion; and
a particle size of the ceramic included at an end of each of the first internal electrode layers on a second end surface side of the inner layer portion is smaller than a particle size of the ceramic included in the central portion of the inner layer portion.

2. The multilayer ceramic electronic component according to claim 1, wherein
a concentration of an additive included on the first lateral surface side of the inner layer portion is higher than a concentration of the additive included in the central portion of the inner layer portion in the width direction;
a concentration of the additive included on the second lateral surface side of the inner layer portion is higher than a concentration of the additive included in the central portion of the inner layer portion in the width direction;
a concentration of the additive included at an end of the second internal electrode layer on the first end surface side of the inner layer portion is higher than a concentration of the additive included in the central portion of the inner layer portion; and
a concentration of the additive included at an end of the first internal electrode layer on the second end surface side of the inner layer portion is higher than a concentration of the additive included in the central portion of the inner layer portion.

3. The multilayer ceramic electronic component according to claim 2, wherein
the additive includes at least one of Ni, Mn, and Mg;
the particle size of the ceramic included on the first lateral surface side of the inner layer portion is smaller by at least about 10% and no more than about 40% compared to the particle size of the ceramic included in the central portion of the inner layer portion in the width direction;
the particle size of the ceramic included on the second lateral surface side of the inner layer portion is smaller by at least about 10% and no more than about 40% compared to the particle size of the ceramic included in the central portion of the inner layer portion in the width direction;
the particle size of the ceramic included at the end of the second internal electrode layer on the first end surface side of the inner layer portion is smaller by at least about 10% and no more than about 40% compared to the particle size of the ceramic included in the central portion of the inner layer portion; and
the particle size of the ceramic included at the end of the first internal electrode layer on the second end surface side of the inner layer portion is smaller by at least about 10% and no more than about 40% compared to the particle size of the ceramic included in the central portion of the inner layer portion.

4. The multilayer ceramic electronic component according to claim 2, wherein
the concentration of the additive included on the first lateral surface side of the inner layer portion is between about 100.1 mol % and about 103.0 mol % inclusive relative to the concentration of the additive included in the central portion of the inner layer portion in the width direction;
the concentration of the additive included on the second lateral surface side of the inner layer portion is between about 100.1 mol % and about 103.0 mol % inclusive relative to the concentration of the additive included in the central portion of the inner layer portion in the width direction;
the concentration of the additive included at the end of the second internal electrode layer on the first end surface side of the inner layer portion is between about 100.1 mol % and about 103.0 mol % inclusive relative to the concentration of the additive included in the central portion of the inner layer portion in the length direction; and
the concentration of the additive included at the end of the first internal electrode layer on the second end surface side of the inner layer portion is between about 100.1 mol % and about 103.0 mol % inclusive relative to the concentration of the additive included in the central portion of the inner layer in the length direction.

5. The multilayer ceramic electronic component according to claim 2, wherein
a range with the highest concentration of the additive extends for a distance between 0 μm and about 60 μm inclusive from an end of a first lateral surface of the inner layer portion towards the central portion in the width direction; and
a range with the highest concentration of the additive extends for a distance between 0 μm and about 60 μm inclusive from an end of a second lateral surface of the inner layer portion towards the central portion in the width direction.

6. The multilayer ceramic electronic component according to claim 2, wherein
a range with the highest concentration of the additive extends for a distance between 0 μm and about 60 μm inclusive from the end of the second internal electrode layer on the first end surface side of the inner layer portion towards the central portion in the length direction; and
a range with the highest concentration of additives extends for a distance between 0 μm and about 60 μm inclusive from the end of the first internal electrode layer on the second end surface side of the inner layer portion towards the central portion in the length direction.

7. The multilayer ceramic electronic component according to claim 1, wherein
the multilayer body includes an outer layer portion made of a dielectric material;
the outer layer portion includes:
a first main surface-side outer layer portion on a first main surface side, provided between the first main surface and an outermost surface of the inner layer portion on the first main surface side in the lamination direction;
a second main surface-side outer layer portion on a second main surface side, provided between the second main surface and an outermost surface of the inner layer portion on the second main surface side in the lamination direction;
a first end surface-side outer layer portion on the first end surface side, provided between an outermost surface on the first end surface side and an outermost surface of the end of the second internal electrode layer that is not connected to the first external electrode;
a second end surface-side outer layer portion provided on the second end surface side, provided between an outermost surface on the second end surface side and an outermost surface of the end of the first internal electrode layer that is not connected to the second external electrode; and
a lateral surface-side outer layer portion provided in portion of the first end surface-side outer layer portion, portion of the second end surface-side outer layer portion, portion of the first main surface-side outer layer portion, and portion of the second main surface-side outer layer portion.

8. The multilayer ceramic electronic component according to claim 7, wherein
the lateral surface-side outer layer portion includes an outer layer near the first and second lateral surfaces, and an inner layer more inward than the outer layer in the width direction;
Si content in the outer layer is greater than Si content in the inner layer; and
Ni content in the outer layer is less than Ni content in the inner layer.

9. The multilayer ceramic electronic component according to claim 7, wherein
a molar ratio of Si to Ti in the lateral surface-side outer layer portion is between about 1.0 and about 7.0 inclusive.

10. The multilayer ceramic electronic component according to claim 7, wherein
a dimension of the lateral surface-side outer layer portion along the width direction is between about 5 μm and about 40 μm inclusive.

11. The multilayer ceramic electronic component according to claim 1, wherein
the dielectric layers include a first dielectric layer and a second dielectric layer;
the first dielectric layer is provided between the first internal electrode layer and the second internal electrode layer;
the second dielectric layer includes a region that does not include the internal electrode layers between the first dielectric layers opposing across the internal electrode layers, and that partially overlaps with the first dielectric layers in the lamination direction; and
the second dielectric layer is provided in at least portion of a first lateral surface-side outer layer portion, a second lateral surface-side outer layer portion, the first end surface-side outer layer portion, and the second end surface-side outer layer portion.

12. The multilayer ceramic electronic component according to claim 11, wherein
in a plane encompassing both the length direction and the width direction, a particle size of the ceramic in a central portion of the first dielectric layer is greater than a particle size of the ceramic in the first dielectric layer corresponding to a region extending about 60 μm inward from the end of the internal electrode layer; and
in a plane encompassing both the length direction and the width direction, a particle size of the ceramic in the central portion of the first dielectric layer is greater than a particle size of the ceramic in the second dielectric layer.

13. The multilayer ceramic electronic component according to claim 7, wherein
the dielectric layers include a first dielectric layer and a second dielectric layer;
the first dielectric layer is provided between the first internal electrode layer and the second internal electrode layer;
the second dielectric layer includes a region that does not include the internal electrode layers between the first dielectric layers opposing across the internal electrode layers, and that partially overlaps with the first dielectric layer in the lamination direction;
the second dielectric layer is provided in at least portion of a first lateral surface-side outer layer portion, a second lateral surface-side outer layer portion, the first end surface-side outer layer portion, and the second end surface-side outer layer portion;
in a plane encompassing both the length direction and the width direction, an interface is defined between the second dielectric layer, the first or second internal electrode layer, and the lateral surface-side outer layer portion;
in a plane encompassing both the length direction and the width direction, a particle size of the ceramic in the first dielectric layer in a region extending about 60 μm inward from an end of the lateral surface-side outer layer portion is larger than a particle size of the ceramic in a region in which a region extending about 60 μm inward from the end of the lateral surface-side outer layer portion overlaps with a region extending about 60 μm inward from an end of the second dielectric layer; and
in a plane encompassing both the length direction and the width direction, a particle size of the ceramic defined at an interface between the second dielectric layer, the first or second internal electrode layer, and the lateral surface-side outer layer portion is the smallest.

14. The multilayer ceramic electronic component according to claim 1, wherein
the thickness of each of the dielectric layers is preferably between about 0.5 μm and about 10 μm inclusive.

15. The multilayer ceramic electronic component according to claim 1, wherein
the first internal electrode layers include first counter electrode portions opposing the second internal electrode layers and first extension electrode portions extending from the first counter electrode portions to the first end surface; and
the second internal electrode layers include second counter electrode portions opposing the first internal electrode layers and second extension electrode portions extending from the second counter electrode portions to the second end surface.
